(19) United States
(12) Patent Application Publication
(10) Pub. No.: US 2025/0393146 A1
(43) Pub. Date: Dec. 25, 2025

(54) SYSTEM AND METHOD FOR CABLE MANAGEMENT DEVICE

(71) Applicant: Langdon Skunkworx Inc., Mesa, AZ (US)

(72) Inventors: James Ruffin, Chandler, AZ (US); Mitchell Booth, Queen Creek, AZ (US); Ernest Langdon, Gilbert, AZ (US)

(73) Assignee: Langdon Skunkworx Inc., Mesa, AZ (US)

(21) Appl. No.: 19/247,133

(22) Filed: Jun. 24, 2025

Related U.S. Application Data
(60) Provisional application No. 63/663,876, filed on Jun. 25, 2024.

(51) Int. Cl. H05K 5/02

(52) U.S. Cl. CPC H05K 5/0247

(57) ABSTRACT

Methods and apparatus for a cable management system according to various aspects of the present technology comprise a textured surface having an integrated pattern configured to provide a customizable routing path for one or more cables or wires. The textured surface forms a low-profile attachment mechanism that can be coupled to the surface of a device or piece of equipment and conform to the shape of the device it is coupled to. The textured surface is designed to allow a cable to be routed in a manner to reduce the amount of loose or dangling cable and allow for the re-routing of the cable without tools or mechanical fasteners. The textured surface may also comprise a series of different sized channels to accommodate varying cable thicknesses.

### CROSS REFERENCES TO RELATED APPLICATIONS

This application claims the benefit of U.S. Provisional Patent Application No. 63/663,876, filed Jun. 25, 2024, and incorporates the disclosure of the application by reference.

### BACKGROUND OF TECHNOLOGY

Technological advancements have led to expanded use of powered accessories and peripheral devices connected to a base device. For example, tactical lights and laser optics designed for use with firearms are typically configured to be mounted along the barrel of a rifle or the upper body of a handgun. Often these devices may not have a built in power and are connected to a power supply located elsewhere on the firearm. As a result a cable must be run from the power supply to the device. The length of the cable running between the power supply and the device may dictate how far apart the device and power supply can be positioned from each other. A more cumbersome result is that unless the cable is secured to the firearm, it can dangle from the firearm and get caught on other objects during use.

Similarly, cable management systems are required in other applications where accessory devices are connected to a primary device. For example, in astrophotography, devices such as a camera, an automatic focuser, a filter wheel, and a mini computer may all be attached to a telescope which itself is connected to a tracking mount. Each device may require a power cable and/or a data cable resulting in between four and ten cables. During operation, the mount may rotate the telescope through two different axes of motion increasing the likelihood that any loose cables may get caught or snagged and impede the motion of the mount or damage the equipment.

Use of some type of cable management system can reduce the chances of snagged cables. Simple methods such as zip ties or wire ties may be used but may have limited effectiveness because the connection isn't secure or from a lack of stable points of attachment. Another option includes the use of a clip or other retention device that must be mounted to the firearm. These options are also limited in effectiveness due to a limited point of attachment and routing options.

### SUMMARY OF THE TECHNOLOGY

Methods and apparatus for a cable management system according to various aspects of the present technology comprise a textured surface having an integrated pattern configured to provide a customizable routing path for one or more cables or wires. The textured surface forms a low-profile attachment mechanism that can be coupled to the surface of a device or piece of equipment and conform to the shape of the device it is coupled to. The textured surface is designed to allow a cable to be routed in a manner to reduce the amount of loose or dangling cable and allow for the re-routing of the cable without tools or mechanical fasteners. The textured surface may also comprise a series of different sized channels to accommodate varying cable thicknesses.

### BRIEF DESCRIPTION OF THE DRAWINGS

A more complete understanding of the present technology may be derived by referring to the detailed description when considered in connection with the following illustrative figures. In the following figures, like reference numbers refer to similar elements and steps throughout the figures.

FIG. 1 representatively illustrates a cable management device in accordance with an exemplary embodiment of the present technology;

FIG. 2 representatively illustrates the cable management device of FIG. 1 with a conforming sidewall in accordance with an exemplary embodiment of the present technology;

FIG. 3 representatively illustrates the cable management device of FIG. 1 with an alternative embodiment of a conforming sidewall in accordance with an exemplary embodiment of the present technology;

FIG. 4 representatively illustrates the cable management device of FIG. 1 coupled to a handguard of a firearm in accordance with an exemplary embodiment of the present technology;

FIG. 5 representatively illustrates an amount of cable routed through the cable management device of FIG. 1 in accordance with an exemplary embodiment of the present technology;

FIG. 6 representatively illustrates the cable management device of FIG. 5 with an amount of free cable arranged in an alternative orientation through the cable texture in accordance with an exemplary embodiment of the present technology;

FIG. 7 representatively illustrates the cable management device of FIG. 5 with the cable routed along another direction to provide a lesser additional amount of free cable in accordance with an exemplary embodiment of the present technology;

FIG. 8 representatively illustrates the cable management device of FIG. 7 with the cable routed to provide an additional amount of free cable in accordance with an exemplary embodiment of the present technology;

FIG. 9 representatively illustrates the cable management device installed on a device in accordance with an exemplary embodiment of the present technology; and

FIG. 10 representatively illustrates the cable management device installed on a portion of a picatinny rail in accordance with an exemplary embodiment of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various materials, finishes, dimensions, and geometries, which may carry out a variety of operations suited to a specified application or environment. In addition, the present technology may be practiced in conjunction with any number of systems configured for managing loose cables, wires, cords, and the like (hereinafter jointly referenced as a “cable” or “cables”), and the system described is merely one exemplary application for the technology. Further, the present technology may employ any number of conventional manufacturing techniques such as machining, additive manufacturing, extrusion, and molding.

A system and device for a cable management according to various aspects of the present technology may operate in conjunction with any type of material. Various representative implementations of the present technology may be applied to the efficient routing of cabling, wiring, and other cords in fixed locations and on portable devices. For example, the described technology may be used to route a power cable in a manner that reduces the amount of freely hanging cable that could catch or get entangled on another object.

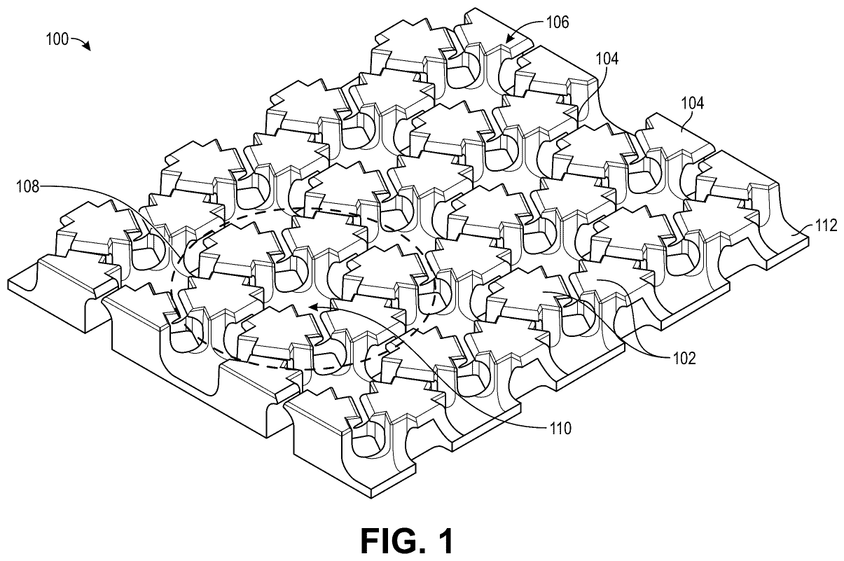

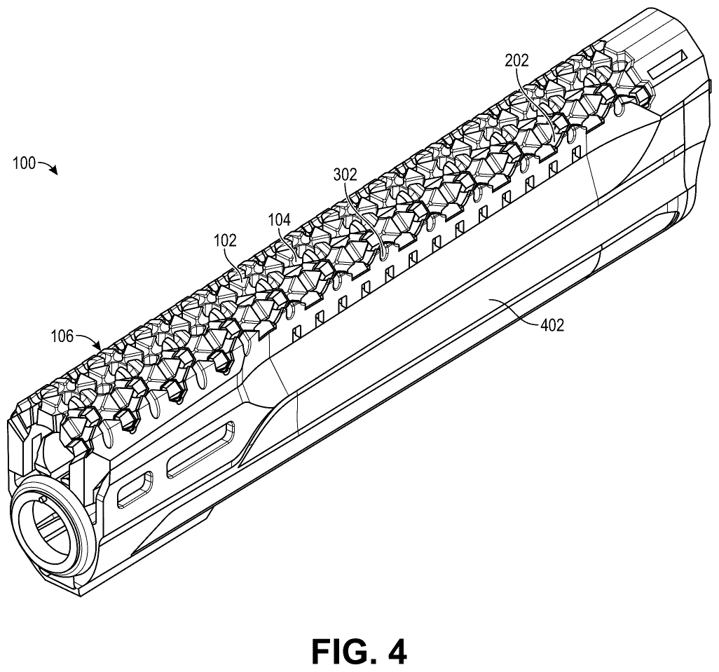

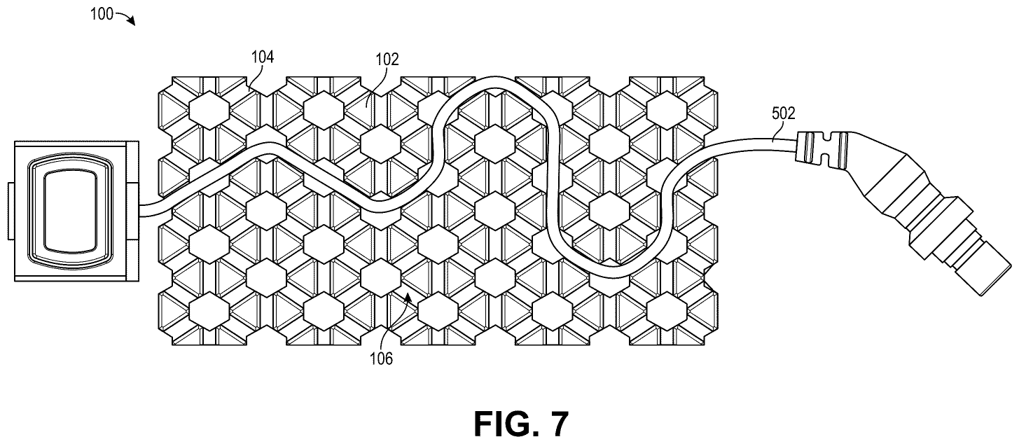

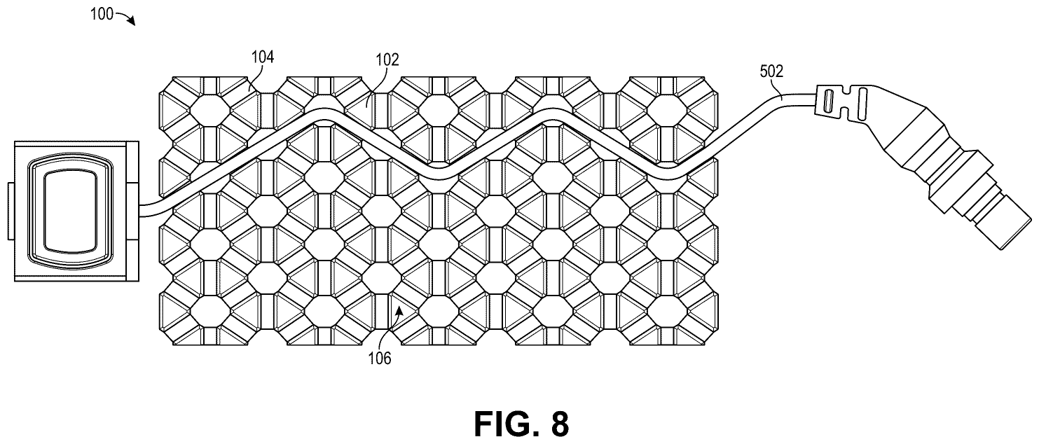

A cable management device may comprise any suitable components configured to allow for a cable/wire to be selectively positioned and securely held in place along a length and width of the device. For example, referring to FIGS. 1-8, a cable management device 100 may comprise a textured body having a plurality of surface elements 102 extending upward from a base 112 and separated by a series of channels 104. The surface elements 102 and channels 104 may be arranged to form a series of routing textures 106 along the length and width of the cable management device 100.

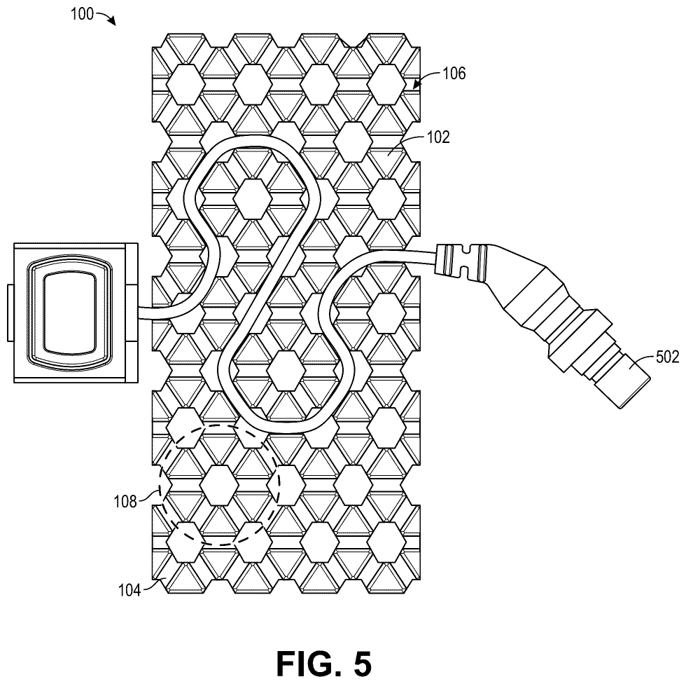

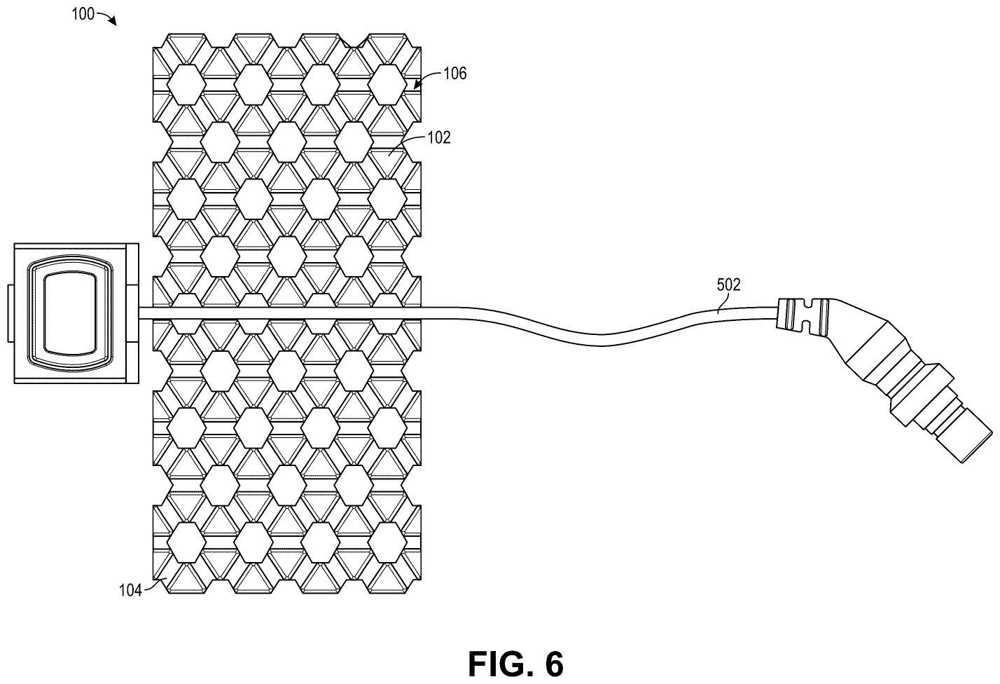

The channels 104 may be arranged to selectively receive a cable 110 that is routed along a top surface of the base 112 in a non-permanent manner that allows for excess cable to be securely attached to the cable management device 100 without having any overly sharp bends or turns that might damage the internal wiring of the cable. A user may selectively reposition or re-route the cable through the channels 104 as desired without the need for tools or mechanical fasteners. For example, the channels 104 may be arranged to form both a linear option for holding a cable 502 (See e.g., FIG. 6) or a curvilinear (non-linear) option for routing a cable 110 in a manner that reduces the amount of freely hanging cable (See e.g., FIGS. 5, 7, and 8).

Walls of the channels 104 may be defined but the upwardly extending portion of the surface elements 102. These walls may comprise any suitable shape or size and may be determined according to a desired application. For example, in one embodiment, at least a portion of the wall may be curved to better conform to or receive a rounded cable or wire. In an alternative embodiment, the walls may be substantially rectangular to better accommodate a thin flat wire or cable.

The surface elements 102 and channels 104 may be arranged to form a grid pattern configured to allow for one or more cables to be routed over the base 112. For example, and with particular reference to FIGS. 1-3, in one embodiment six surface elements 102 wherein each surface element 102 is separated from another surface element 102 by a channel 104 may be arranged to form a plurality of circular textures 108 having an open center 110. The arrangement of the surface elements 102 may create a pattern of repeating or overlapping circular textures 108. The channels 104 may comprise a width configured to receive and securely hold a cable 110 between two adjacent surface elements 102. The open center 110 may be large enough to receive more than two cables to allow multiple cables to pass through.

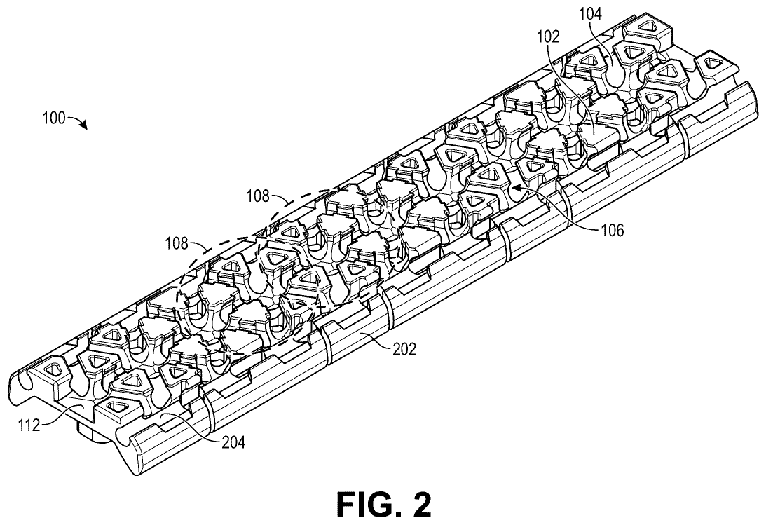

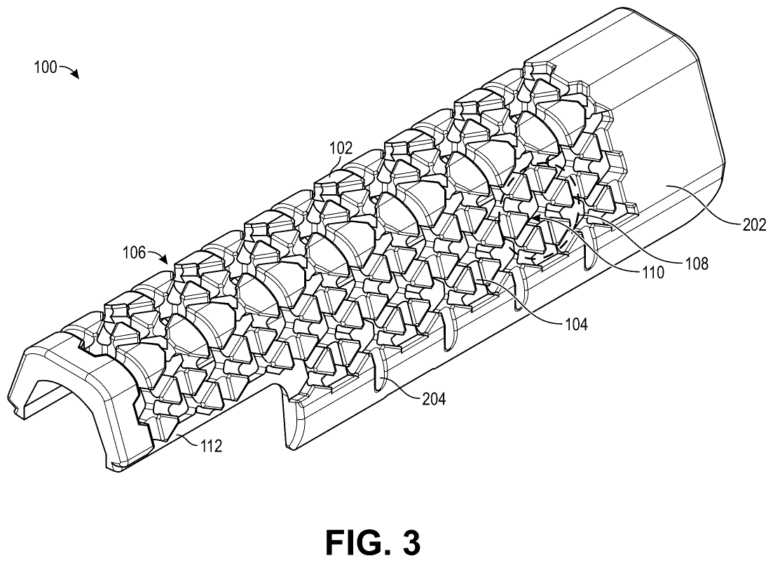

The surface elements 102 may comprise any suitable shape or size for helping to create the textures 106. For example, as shown in FIGS. 1 and 2, in one representative embodiment, each surface element 102 may comprise a body of varying geometry and be arranged in a pattern to form the textures 106. Each surface element 102 may comprise one or more edge portions that are oriented parallel to an edge portion of an adjacent surface element 102. In another embodiment, and referring now to FIGS. 3 and 5-8, each surface element 102 may comprise a generally triangular shaped body and be arranged in an alternating pattern of ordered triangles to form the plurality of circular textures 108. In some embodiments, the surface elements 102 may comprise multiple shapes and sizes and be configured to hold and secure cables 110 of various sizes along the same surface. In some other representative embodiments, the surface elements 102 may comprise a material that is somewhat flexible or compressible to allow for a cable 110 to be inserted into the channels 104 and be held in place.

The surface elements 102 may also comprise one or more lips or overhangs above the channels 104 configured to retain the wire within the channel 104. For example, each lip of a surface element 102 may extend outward towards an opposing adjacent surface element 102 such that a gap between opposing lips forming an uppermost portion of the channel 104 is smaller than a gap between a lower portion of the channel 104. The surface elements 102 may also be configured to be semi-flexible to allow a pair of opposing lips to be at least temporarily separated when a cable or wire is inserted into the channel 104. The lip may be formed as part of edge portion of each surface element 102 or the lip may comprise a protrusion extending outward from the edge portion.

A top or outward facing portion of the surface elements 102 may also be configured to provide increased grip or slip resistance. For example, in an embodiment used on a forward portion of a firearm, the top or outward facing portion of the surface elements 102 may include a surface treatment intended to increase a user's grip. The surface treatment may comprise any suitable structure or method for increasing surface friction such as checkering, knurling, stippling, or an adhesive overlay such as a tape or sprayed on surface.

The textures 106 may comprise any generally repeating shape or pattern to allow for the routing of a cable 110 along the base 112 of the cable management device 100. Alternatively, the textures 106 may also form a randomized surface having no discernable pattern other than to allow for a customizable routing over the top surface of the cable management device 100.

The base 112 and surface elements 102 may comprise any suitable material and may be rigid or semi-rigid according to a desired application such as rubber, metal, carbon fiber, plastic, thermoplastic polymer, such as acrylonitrile butadiene styrene or 3D printed material such as nylon, and the like. For example, in one embodiment, the base 112 and surface elements 102 may comprise a slightly soft or compressible material configured to yield slightly in response to a cable or wire being inserted into a channel 104. Alternatively, in another embodiment, the base 112 and surface elements 102 may comprise a stiff or rigid material configured to press into an outer surface of the cable or wire being inserted into a channel 104. For example, in a larger application, a hose or tube made of a polymer material may compress inwardly in response to being inserted into the channel 104.

The cable management device 100 may be configured to be connected to another body such as a barrel of a firearm, picatinny rail, desk, helmet, entertainment unit, computer case, clothing, or any other surface where it may be desirous to manage one or more cables. In larger scaled installations, the cable management device 100 may be configured to be located along floors, walls, or buried to facilitate the arrangement of hoses for cooling channels using air or liquids.

In a first representative example and with reference now to FIGS. 2-4, the cable management device 100 may be configured to be connected to a surface of an object such as a firearm. The base 112 may form a body having one or more sidewalls 202 configured to conform to one or more surfaces of the firearm 402. The sidewalls 202 may comprise a second channel 204 configured to help feed the cable into the channel 104 of the textures 106. The cable management device 100 may be coupled to the object by any suitable method. In one embodiment, the sidewalls 202 may be rigid and configured conform to the object and be held in place through a compression fit. Alternatively, the cable management device 100 may be coupled to the object with a mechanical fastener, adhesive material, or magnet.

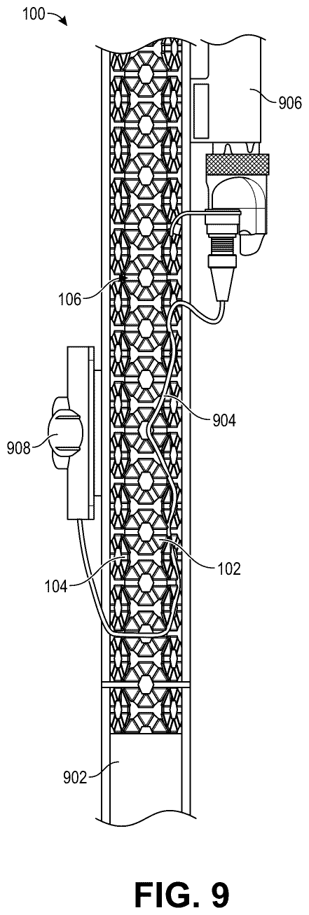

For example, and referring now to FIG. 9, the cable management device 100 may be coupled to the barrel 902 of a rifle to allow a power cable 904 to be routed from a power supply 908 to a tactical light 906. The power cable 904 may be routed through the channels 104 in a manner that prevents the power cable 904 from having any freely hanging sections that could get caught or snagged during use.

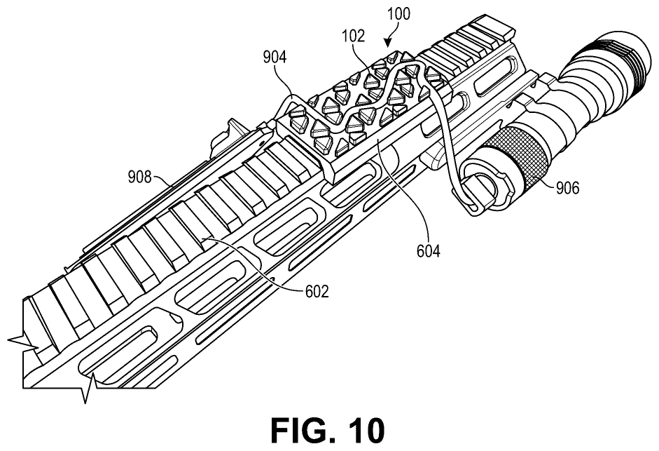

Referring now to FIG. 10, in another embodiment, the cable management device 100 may be configured to be attached to a picatinny rail 1002 to allow for the routing of the power cable 904. For example, the surface elements 102 and channels 104 of the cable management device 100 may be disposed along an upper surface of a picatinny mounting plate 1004 that is configured to be connected to the rail 1002 at a desired location.

The particular implementations shown and described are illustrative of the technology and its best mode and are not intended to otherwise limit the scope of the present technology in any way. Indeed, for the sake of brevity, conventional manufacturing, connection, preparation, and other functional aspects of the system may not be described in detail. Furthermore, the connecting lines shown in the various figures are intended to represent exemplary functional relationships and/or steps between the various elements. Many alternative or additional functional relationships or physical connections may be present in a practical system.

In the foregoing description, the technology has been described with reference to specific exemplary embodiments. Various modifications and changes may be made, however, without departing from the scope of the present technology as set forth. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any appropriate order and are not limited to the explicit order presented in the specific examples. Additionally, the components and/or elements recited in any system embodiment may be combined in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

As used herein, the terms “comprises,” “comprising,” or any variation thereof, are intended to reference a non-exclusive inclusion, such that a process, method, article, composition or apparatus that comprises a list of elements does not include only those elements recited but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same. Any terms of degree such as “substantially,” “about,” and “approximate” as used herein mean a reasonable amount of deviation of the modified term such that the end result is not significantly changed. For example, these terms can be construed as including a deviation of at least ±5% of the modified term if this deviation would not negate the meaning of the word it modifies.

The present technology has been described above with reference to an exemplary embodiment. However, changes and modifications may be made to the exemplary embodiment without departing from the scope of the present technology. These and other changes or modifications are intended to be included within the scope of the present technology.

1. A cable management device, comprising:
a plurality of surface elements extending upwardly from a base; and
a plurality of channels running between the plurality of surface elements, wherein:
the plurality of surface elements and the plurality of channels are arranged about the base to form a series of routing textures along a length and width of the base; and
the plurality of channels are configured to receive a cable.

2. A cable management device according to claim 1, wherein the plurality of channels are arranged to allow the cable to be routed along the base in a non-linear path.

3. A cable management device according to claim 2, wherein the series of routing textures comprises a grid pattern.

4. A cable management device according to claim 2, wherein the series of routing textures comprises a plurality of circular textures formed from a set of surface elements arranged around a central open area.

5. A cable management device according to claim 4, wherein the surface elements comprises a triangular shape.

6. A cable management device according to claim 5, wherein the surface elements are arranged such that the plurality of circular textures overlap one another in a repeating manner along the length and width of the base.

7. A cable management device according to claim 1, wherein the base further comprises a pair of opposing sidewalls configured to couple the base to another object.

8. A cable management device according to claim 7, wherein the pair of opposing sidewalls conform to a portion of the other object.

9. A cable management device for selectively routing a cable along a surface of a device, comprising:
a base configured to be coupled to the surface of the device;
a plurality of surface elements disposed along and extending upwardly from the base, wherein each of the plurality of surface elements comprises an edge portion configured to be oriented parallel to an opposing edge portion of an adjacent surface element;
a plurality of channels running between the plurality of surface elements, wherein:
the plurality of surface elements and the plurality of channels are arranged about the base to form a series of routing textures along a length and width of the base; and
the plurality of channels are configured to receive a cable in a non-permanent manner.

10. A cable management device for selectively routing a cable along a surface of a device according to claim 9, wherein the plurality of channels are arranged to allow the cable to be routed along the base in a non-linear path.

11. A cable management device for selectively routing a cable along a surface of a device according to claim 9, wherein the series of routing textures comprises a grid pattern.

12. A cable management device for selectively routing a cable along a surface of a device according to claim 9, wherein the series of routing textures comprises a plurality of circular textures formed from a set of surface elements arranged around a central open area.

13. A cable management device for selectively routing a cable along a surface of a device according to claim 12, wherein the surface elements comprises a triangular shape.

14. A cable management device for selectively routing a cable along a surface of a device according to claim 13, wherein the surface elements are arranged such that the plurality of circular textures overlap one another in a repeating manner along the length and width of the base.

15. A cable management device for selectively routing a cable along a surface of a device according to claim 9, wherein the edge portion of each surface element comprises a lip configured to extend outwardly over the channel.

16. A cable management device for selectively routing a cable along a surface of a device according to claim 9, wherein each channel comprises rounded walls.

17. A cable management device for selectively routing a cable along a surface of a device according to claim 9, wherein the base further comprises a pair of opposing sidewalls configured to couple the base to another object.

18. A cable management device for selectively routing a cable along a surface of a device according to claim 17, wherein the pair of opposing sidewalls conform to a portion of the other object.
